(19) United States
(12) Patent Application Publication
(10) Pub. No.: US 2015/0001992 A1
(43) Pub. Date: Jan. 1, 2015

(54) Removable Piezoelectric Keyboard Cover with Outlet and Lighting System

(71) Applicant: Amol Jay Kapoor, Basking Ridge, NJ (US)

(72) Inventor: Amol Jay Kapoor, Basking Ridge, NJ (US)

(21) Appl. No.: 13/929,752

(22) Filed: Jun. 27, 2013

(51) Int. Cl. H01L 41/113

(52) U.S. Cl. CPC H01L 41/113
USPC 310/314

(57) ABSTRACT

Piezoelectric energy can be gathered from rapid pressure changes, such as those applied to keyboards when typing. A piezoelectric array is embedded within a removable keyboard cover that slides to fit any keyboard configuration (i.e. any machine with buttons). The array is attached to a battery that can store energy for future use. The battery is attached to an outlet to distribute power gleaned from the battery and to an internal lighting mechanism within each key of the keyboard cover. A regulator for the battery in the form of a switch may be used to control energy flow.

### BACKGROUND

The invention relates to piezoelectric generating devices, and particularly, to a keyboard cover used to generate electricity from rapid pressure change.

Many portable machines have a finite battery life that often requires an outlet and charging station to recharge.

Running external devices or keyboard lighting takes up limited battery life.

Built in piezoelectric arrays and keyboard lighting mechanisms are costly and require extensive repairs if broken.

Many keyboards already in existence do not have lighting mechanisms or piezoelectric power capturing and storage.

Therefore, a removable and replaceable piezoelectric array and lighting array powered by said piezoelectric array are desirable to conserve and/or recharge computer battery while providing convenient power functionality.

Note that keyboard does not specify to a computer keyboard, although it may.

### FIGURE DESCRIPTION (BASED AROUND A COMPUTER KEYBOARD)

FIG. 1: A standard ‘qwerty’ keyboard

FIG. 2: Side view of key cover layout

FIG. 3: An exploded view of key cover of FIG. 2

### INVENTION DESCRIPTION

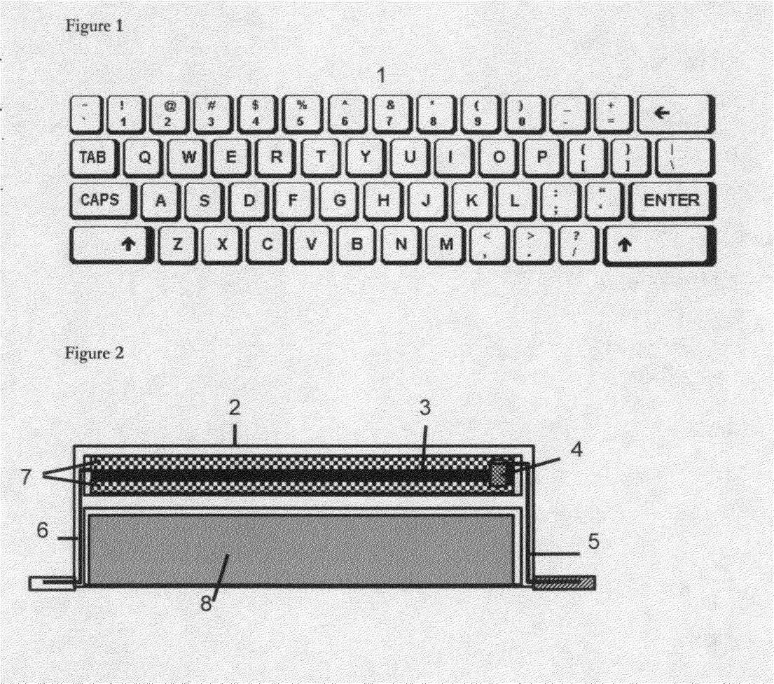

1. Referring FIG. 1, an ideal cover configuration is one that fits each key on the keyboard 1, and is not necessarily in the layout described.

2. Referring FIG. 2, a key cover is composed of a top and bottom layer of cover material 2, which encases a piezoelectric pad 3 and a light 4. The pressure supports 7 are designed to maximise pressure change on the piezoelectric pad 3, and do not have to be configured as shown. The light 4 is wired to an input wire 5, while the piezoelectric pad 3 is wired to an output wire 6.

3. Referring FIG. 2, the key cover completely and tightly surrounds the key 8.

4. Referring FIG. 2, the key cover will push down upon the key 8 when keyboard is in use, putting pressure on the piezoelectric pad 3.

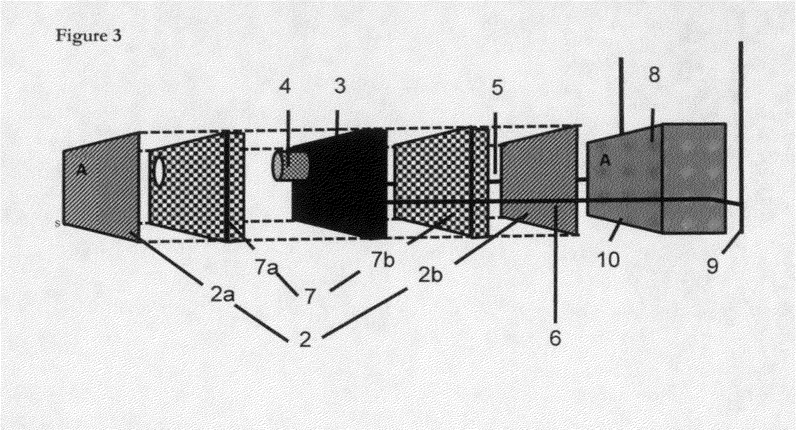

5. Referring FIG. 3, in an ideal configuration, the top cover 2a is labeled with the letter of the corresponding key 8 above the light source 4, in order to allow each key to light up.

6. Referring FIG. 3, in an ideal configuration, top support 7a will wrap around light source 4 to maximize pressure on piezoelectric plate 3.

7. Referring FIG. 3, in an ideal configuration, input wire 5 and output wire 6 will respectively join a central input wiring array 10 and central output wiring array 9.

8. The battery (not shown) is linked to and stores energy from the central output wiring array 9, gathering energy from the piezoelectric plates 3.

9. The battery (not shown), in an ideal configuration, can be regulated with a sliding switch (not shown) to determine how much energy is returned to the light 4 array.

10. The battery (not shown), in an ideal configuration, is attached to an power distributing device (not shown) to power external devices.

11. Pressure applied on each key will lead to energy release from each piezoelectric pad 3 and energy storage in the battery (not shown), to be used at user digression to light the keyboard cover or power external devices.

12. The keyboard cover is its own entity. In other words, it can be freely removed and added to a keyboard and does not necessarily need a keyboard to function.

13. It is to be understood that even though numerous characteristics and advantages of the present embodiments have been set forth in the foregoing description, together with details of the structures and functions of the embodiments, the disclosure is illustrative only, and changes may be made in details, especially in matters of shape, size, and arrangement of parts within the principles of the disclosure to the full extent indicated by the broad general meaning of the terms in which the appended claims are expressed.

1. A cover designed to store pressure-mechanical energy as electrical energy using a piezoelectric material, shaped to fit any machine with keys/buttons (e.g. computer keyboards, electric pianos, etc.) such that it can be easily removed from the machine it is covering, designed such that each key has an individual pressure sensitive section comprised of: a bottom layer of soft rubber material, a middle layer of piezoelectric material surrounded by two hard plastics meant to focus pressure onto the piezoelectric material, a light mechanism, and a top layer of soft rubber material.

2. A cover designed to store pressure-mechanical energy as electrical energy using a piezoelectric material, shaped to fit any machine with keys/buttons (e.g. computer keyboards, electric pianos, etc.) such that it can be easily removed from the machine it is covering, designed such that each key has an individual pressure sensitive section comprised of a bottom layer of soft rubber material, a middle layer of piezoelectric material surrounded by two hard plastics meant to focus pressure onto the piezoelectric material, a light mechanism, and a top layer of soft rubber material. The cover contains an attached battery used to store electric charge gathered from the piezoelectric material within the cover and an internal lighting mechanism such that energy gathered from the cover is used to light individual keys. The battery described is regulated by a switch controls whether the battery is being used that is wired to the lighting mechanism.

3. A cover designed to store pressure-mechanical energy as electrical energy using a piezoelectric material, shaped to fit any machine with keys/buttons (e.g. computer keyboards, electric pianos, etc.) such that it can be easily removed from the machine it is covering, designed such that each key has an individual pressure sensitive section comprised of a bottom layer of soft rubber material, a middle layer of piezoelectric material surrounded by two hard plastics meant to focus pressure onto the piezoelectric material, a light mechanism, and a top layer of soft rubber material. The cover contains an attached battery used to store electric charge gathered from the piezoelectric material within the cover and an internal lighting mechanism such that energy gathered from the cover is used to light individual keys. The battery described is regulated by a switch controls whether the battery is being used that is wired to the lighting mechanism. The cover contains an adaptor attached to the battery described above that can be used to power an external device (e.g. USB devices, computers, electric pianos, wireless keyboards, etc.).
